(19) United States
(12) Patent Application Publication
(10) Pub. No.: US 2024/0353473 A1
(43) Pub. Date: Oct. 24, 2024

(54) Computer-Implemented Method for Determining a Quality State of a Wafer

(71) Applicant: Robert Bosch GmbH, Stuttgart (DE)

(72) Inventors: Jonas Bergdolt, Bietigheim-Bissingen (DE); Maria Irina Nicolae, Stuttgart (DE); Michel Janus, Kirchentellinsfurt (DE); Moritz Gronbach, München (DE)

(21) Appl. No.: 18/638,946

(22) Filed: Apr. 18, 2024

(30) Foreign Application Priority Data
Apr. 19, 2023 (DE) 10 2023 203 582.0

(51) Int. Cl. G01R 31/28

(52) U.S. Cl. CPC G01R 31/2831; G01R 31/2834

(57) ABSTRACT

A computer-implemented method determines a quality state of a wafer. The method includes providing at least three process control monitoring metrics of the wafer. Each process control monitoring metric is collected on the wafer at a different process control monitoring coordinate. The method further includes inputting the at least three process control monitoring metrics and the different process control monitoring coordinates of the process control monitoring metrics into at least one machine learning algorithm, and outputting at least three approximated wafer level test values by the at least one machine learning algorithm. The method also includes determining the quality state of the wafer based on the at least three approximated wafer level test values.

This application claims priority under 35 U.S.C. § 119 to patent application no. DE 10 2023 203 582.0, filed on Apr. 19, 2023 in Germany, the disclosure of which is incorporated herein by reference in its entirety.

The disclosure relates to a computer-implemented method for determining a quality state of a wafer, the method comprises the provision of at least three process control monitoring metrics of the wafer, each process control monitoring metrics being collected at a different process control monitoring coordinate on the wafer.

### BACKGROUND

According to known methods for checking a quality state of a wafer, a single wafer level test value (WLT) is determined for the entire wafer using test results from process control monitoring (PCM).

A drawback of this method is that the decision about the quality of the wafer is made for the entire wafer and not for certain areas of the chips on the wafer. If the wafer level test value is incorrect, the entire wafer is therefore discarded as a reject.

The object of the disclosure is thus to provide a computer-implemented method for determining a quality state of a wafer, which allows as precise a determination as possible of the quality state of the chips on the wafer and as few rejects of the chips on the wafer as possible.

### SUMMARY

The disclosure relates to a computer-implemented method for determining a quality state of a wafer, the method comprising the steps of:
providing at least three process control monitoring metrics of the wafer, wherein each process control monitoring metric is collected at a different process control monitoring coordinate on the wafer;
inputting the at least three process control monitoring metrics and the process control monitoring coordinates of the process control monitoring metrics into at least one machine learning algorithm;
outputting at least three approximated wafer level test values by the at least one machine learning algorithm;
determining the quality state of the wafer based on the approximated wafer level test values.

An advantage of the method is that using the machine learning algorithm, at least three wafer level test values for chips on the wafer are predicted or approximated as accurately as possible using the measured process control monitoring metrics so that an additional measurement of the wafer level test values is not required.

A further advantage of the method is that at least three wafer level test values are determined in different areas of the wafer so that a statement about the quality of the wafer in different areas is made possible.

After manufacturing chips on a wafer, the process control monitoring method (PCM) is used to obtain detailed information about the processes used for particular chips on the wafer for particular process control monitoring coordinates. During the process control monitoring method, special technology-specific parameters of the chips are measured, such as Vth in CMOS and Vbe in Bipolars. In so doing, certain test devices are placed over the wafer at certain process control monitoring coordinates to allow a more accurate insight into the process variation or variation of the process control monitoring metrics of the individual chips. The process control monitoring method consequently measures certain process control monitoring metrics for some chips at process control monitoring coordinates on the wafer.

According to the process control monitoring method (PCM) and according to known methods from the prior art, the so-called wafer level test method (WLT) is used, wherein chips on the wafer are subjected to electrical tests to determine wafer level test values. Moreover, further temperature/bias reliability stress tests may also be performed to determine further wafer level test values. The determined wafer level test values are then used to detect potential failures in the early life cycle of the chips and sort them as rejects. During the wafer level test method on the wafer, the electrical bias required by the chips is applied directly to the connection points (the bond pads or the solder balls/bumps above the bond pads) of each chip on the wafer by means of special test equipment (DUT).

In the present method, the measurement according to the wafer level test method is not performed, but only the wafer level test values based on the process control monitoring metrics are predicted or approximated using the machine learning algorithm.

Machine learning algorithms are also based on statistical methods used to train a data processing system such that it can perform a particular task without being originally programmed explicitly for this purpose. The goal of machine learning is to construct algorithms that can learn and make predictions from data. These algorithms create mathematical models with which data can be classified, for example, and input data can be mapped to output data.

The machine learning algorithm can be trained using artificial neural networks that allow an unknown system behavior to be learned from existing training data and to subsequently apply the learned system behavior even to unknown input variables. The neural network consists of layers with idealized neurons, which are interconnected in different ways according to a topology of the network.

Artificial neural networks are universal function approximators. When training the network, the weights are updated using an error function. With the help of linked neurons that apply the propagation and activation functions, the neural network outputs a number vector. To what extent the result from the artificial neural networks deviates from the expected value is determined with the help of an error function or loss function. There are different types of error functions. An error function or loss function of this is, for example, the mean square error.

Based on the testing of the quality state of the wafer, it can then be decided, for example, whether certain areas or the individual chips on the wafer can be further processed or depleted. To enable such tests to be performed reliably and independently of human senses, the present method is based on a machine learning algorithm. Machine learning algorithms are based on statistical methods being used to train a data processing system in such a way that it can perform a particular task without it having originally been programmed explicitly for this purpose. The goal of machine learning is to construct algorithms that can learn and make predictions from data. These algorithms create mathematical models with which data can be classified, for example. For predicting or approximating the wafer level test values based on the measured process control monitoring metrics, the machine learning algorithm can be trained according to the disclosure, for example, using older training data including data sets of measured process control monitoring metrics and measured wafer level test values of already manufactured wafers. Training using the training data may then be performed until a sufficient error range is achieved between the predicted wafer level test values and the actual measured wafer level tests.

The process control monitoring coordinates of the process control monitoring metrics can be arranged evenly distributed on the wafer and not lie on a line in order to be able to span a polygon between the monitoring coordinates.

Advantageously, for each process control monitoring metric at the respective coordinate, a wafer level test value can be approximated at that process control monitoring coordinate using the machine learning algorithm for that process control monitoring metric, wherein a polygon is spanned between the process control monitoring coordinates of the individual process control monitoring metrics.

As a result, the machine learning algorithm can be trained with training data of a process control monitoring metric at a specific process control monitoring coordinate and the corresponding wafer level, so that the reliability of the prediction or approximation is improved.

A polygon is spanned between the at least three process control monitoring coordinates, such that a particular area of the wafer is comprised by that polygon.

Advantageously, further wafer level test values for chips within the polygon may be determined by linear interpolation between the predicted wafer level test values at the process control monitoring coordinates of the process control monitoring metrics.

As a result, a reliable prediction of the wafer level test values for chips within the polygon can be enabled by linear interpolation. A measurement of these wafer level test values can thereby be eliminated, thereby reducing production costs and production time.

Advantageously, further wafer level test values for chips outside the polygon may be determined by a nearest neighbor method, wherein the wafer level test values outside the polygon are equated with the respective next predicted wafer level test value of one of the process control monitoring coordinates.

This enables reliable prediction of the wafer level test values for chips outside the polygon using the Nearest Neighbor method. As a result, wafer level test values for all the chips on the wafer can be predicted or approximated without having to measure these test values.

Advantageously, at least nine process control monitoring metrics may be measured at different process control monitoring coordinates that are arranged substantially equally distributed on the wafer, wherein by means of the machine learning algorithm, the wafer level test values for all individual chips are determined on the wafer.

As a result, a polygon is spanned between the new process control monitoring metrics and the wafer level test values are predicted within the polygon by linear interpolation and outside the polygon by the Nearest Neighbor method for all the chips on the wafer. This allows the wafer to be divided into areas that meet the quality requirements for the wafer level test values and areas that do not meet these quality requirements and are graded as rejects. Consequently, an area of the wafer that meets the quality requirements can be further used for the further production of the chips.

Advantageously, a message regarding the quality state of respective chips of the wafer may be generated if at least one of the approximated wafer level test values is outside of a predetermined range or exceeds or falls below a predetermined threshold value.

As a result, a user is notified if the quality requirements for the wafer level test values are no longer met. The user may then decide, after an in-depth analysis, which areas of the wafer to mark as rejects.

Advantageously, the machine learning algorithm can be checked by comparing the predicted wafer level test values with actual measured wafer level test values on the wafer, wherein a maximum error value of the deviations is determined, wherein the machine learning algorithm is no longer applied if this maximum error value exceeds a set threshold value.

As a result, the machine learning algorithm may be checked at regular intervals, wherein in particular the maximum error value of the deviations between the predicted wafer level test values and the measured wafer level test values is determined. If the maximum error value is exceeded, a message may be transmitted to the user to indicate to the user that the machine learning algorithm needs to be improved. Subsequently, the machine learning algorithm may be improved by further training with training data or replaced by a retrained machine learning algorithm.

A further subject matter of the disclosure is a method for providing a training machine learning algorithm for approximating wafer level test values based on process control monitoring metrics at different process control monitoring coordinates of a wafer, the method comprising the steps of:
receiving a first training data set comprising a plurality of process control monitoring metrics at different process control monitoring coordinates of the wafer;
receiving a second training data set comprising a plurality of approximated wafer level test values; and
training the machine learning algorithm by an optimization algorithm that calculates an extreme value of a loss function for approximating wafer level test values based on process control monitoring metrics at different process control monitoring coordinates of the wafer.

As a result, the machine learning algorithm is trained by the two provided training datasets to enable reliable prediction of the wafer level test values. The quality of the machine learning algorithm can be improved by selecting the training data and selecting the number of training data.

A further subject matter of the disclosure is a system for determining a quality state of a wafer, comprising a first computing unit configured to provide at least three process control monitoring metrics of the wafer, wherein each process control monitoring metric is collected at a different process control monitoring coordinate on the wafer.

Furthermore, the system comprises an input device configured to input the at least three process control monitoring metrics and the process control monitoring coordinates of the process control monitoring metrics into at least one machine learning algorithm;

Moreover, the system comprises a machine learning algorithm configured to output at least three approximated wafer level test values, as well as a determining means configured to determine the quality state of the wafer based on the approximated wafer level test values.

The system consequently enables the performance of the above computer-implemented method for determining the quality state of a wafer. The computing unit may be any computer, such as a PC.

The input means may be any input device, such as a keyboard or mouse, to manually input the measured process control monitoring metrics. The input device may also automatically read the measured process control monitoring metrics from a measurement device and automatically input them into the machine learning algorithm. The determining means may be a computer, such as a PC, to perform the computer-implemented method.

A further subject matter of the disclosure is a system for providing a training machine learning algorithm for approximating wafer level test values based on process control monitoring metrics at different process control monitoring coordinates of a wafer, comprising:
means for receiving a first training data set comprising a plurality of process control monitoring metrics at different process control monitoring coordinates of the wafer;
Furthermore, the system comprises means for receiving a second training data set comprising a plurality of approximated wafer level test values.

Furthermore, the system comprises a training calculation unit configured to train the machine learning algorithm by an optimization algorithm that calculates an extreme value of a loss function for approximating wafer level test values based on process control monitoring metrics at different process control monitoring coordinates of the wafer.

This enables the system to perform the training of the machine learning algorithm. The means for receiving the training data may be a conventional data transfer means for a computer. The training calculation unit may be configured on a conventional computer, such as a PC.

A further subject matter of the disclosure is a computer program having program code to perform at least portions of the computer-implemented method for determining the quality state of the wafer when the computer program is executed on a computer.

A further subject matter of the disclosure is a computer-readable data carrier having program code of a computer program to perform at least portions of the computer-implemented method for determining the quality state of the wafer when the computer program is executed on a computer.

The computer program and computer-readable data carrier each have the advantage that they are configured to reliably perform the computer-implemented method for determining the quality state of the wafer.

The described embodiments and developments can be combined with one another as desired.

Further possible embodiments, developments and implementations of the disclosure also include not explicitly mentioned combinations of features of the disclosure described above or below with respect to exemplary embodiments.

### BRIEF DESCRIPTION OF THE DRAWINGS

The accompanying drawings are intended to provide a better understanding of the embodiments of the disclosure. They illustrate embodiments and, in connection with the description, serve to explain principles and concepts of the disclosure.

Other embodiments and many of the mentioned advantages become apparent from the drawings. The illustrated elements of the drawings are not necessarily shown to scale with respect to one another.

The figures show:

FIG. 1 a schematic diagram illustrating the computer-implemented method for determining a quality state of a wafer; and

FIG. 2 a schematic diagram illustrating the machine learning algorithm.

### DETAILED DESCRIPTION

In the figures of the drawings, identical reference signs denote identical or functionally identical elements, parts or components, unless stated otherwise.

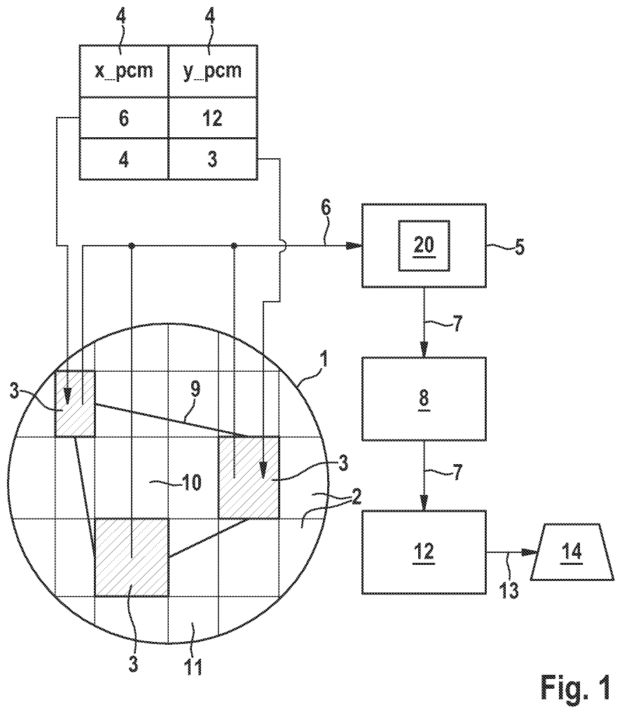

FIG. 1 shows a schematic diagram illustrating the computer-implemented method for determining a quality state of a wafer 1 having a plurality of chips that are schematically shown as rectangles.

At the three chips 3 marked in gray at different process control monitoring coordinates 4 on the wafer, process control monitoring metrics 6 are measured using non-illustrated measuring devices and transferred to a computing unit or input means 5, as shown by the arrow.

The computing unit 5 is configured to perform the machine learning algorithm 20, wherein wafer level test values 7 approximated at the three process control monitoring coordinates 4 are output for the chips as shown by an arrow and transmitted to a further computing unit 8 which is configured to perform the further steps of the method, namely that a polygon 9 is mounted between the process control monitoring coordinates 4.

Further wafer level test values for chips 10 are determined within the polygon by linear interpolation between the predicted wafer level test values 7. Furthermore, further wafer level test values for chips 11 outside the polygon are determined by a Nearest Neighbor method.

Consequently, wafer level test values 7 for all chips 3, 10, and 11 are predicted or approximated on wafer 1 without having to perform a measurement and transmitted from the second computing unit 8 to a determining device 12 configured to determine the quality state of the wafer 1 based on the approximated wafer level test values 7 for all chips 3, 10, and 11.

For example, the determining means 12 may then sort a sub-area of the wafer 1 based on the determined wafer level test values 7 as rejects, as they do not meet the quality requirements. The remaining chips 3, 10 and 11 on the wafer 1, whose approximated wafer level test values 7 meet the quality requirements, can then be further used for further production. This minimizes overall rejects.

If the determining device 12 determines that at least one of the approximated wafer level test values 7 is outside of a predetermined range or exceeds or falls below a predetermined threshold, a message 13 regarding the state of the respective chips 3, 10, 11 of the wafer 1 is generated and transmitted to a display device 14.

The display device 14 can be any visual display device, such as a monitor, an acoustic display device, such as a loudspeaker, or a tactile display device, such as a vibration device, which communicates the message 13 to the user by means of a visual signal, an acoustic signal or a tactile signal. In a further step, the user can then better assess which area of wafer 1 is to be sorted out as rejects.

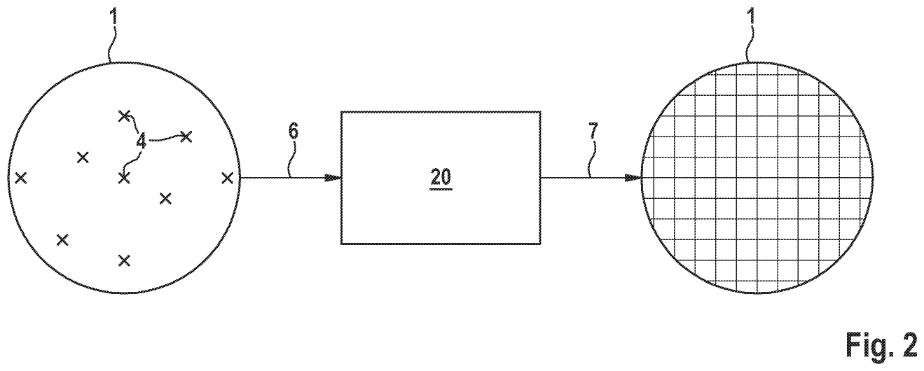

FIG. 2 depicts a schematic diagram illustrating the machine learning algorithm, in which in the present case nine measured process control monitoring metrics 6 are measured at the respective process control monitoring coordinates 4 on the wafer 1 represented by crosses and transmitted as input to a machine learning algorithm 20. Wafer level test values 7 are predicted or approximated at the respective process control monitoring coordinates 4 as output.

In so doing, for each process control monitoring metric 6 at each of the determined coordinates, a wafer level test value 7 may be approximated at that process control monitoring coordinate 4 using a separate machine learning algorithm 20 for that process control monitoring metric 6.

The individual separate machine learning algorithms 20 for the respective process control monitoring coordinate 4 may thereby be independently trained based on the separate training data, namely the process control monitoring metric 6 and the measured wafer level test value 7 for the respective process control monitoring coordinate 4.

What is claimed is:

1. A computer-implemented method for determining a quality state of a wafer, the method comprising:
providing at least three process control monitoring metrics of the wafer, wherein each of the process control monitoring metrics are collected on the wafer at a different process control monitoring coordinate;
inputting the at least three process control monitoring metrics and the different process control monitoring coordinates into at least one machine learning algorithm;
outputting at least three approximated wafer level test values from the at least one machine learning algorithm; and
determining the quality state of the wafer based on the outputted at least three approximated wafer level test values.

2. The computer-implemented method according to claim 1, wherein:
for each of the at least three process control monitoring metrics at a respective monitoring coordinate, a corresponding wafer level test value is approximated at that process control monitoring coordinate using the at least one machine learning algorithm for that process control monitoring metric, and
a polygon is spanned between the process control monitoring coordinates of individual process control monitoring metrics.

3. The computer-implemented method according to claim 2, further comprising:
determining further wafer level test values for chips within the polygon by linear interpolation between predicted wafer level test values at the process control monitoring coordinates of the at least three process control monitoring metrics.

4. The computer-implemented method according to claim 3, further comprising:
determining further wafer level test values for chips outside the polygon by a Nearest Neighbor method,
wherein the wafer level test values outside the polygon are equated with a next predicted wafer level test value of one of the at least three process control monitoring coordinates.

5. The computer-implemented method according to claim 1, further comprising:
measuring at least nine of the process control monitoring metrics at different process control monitoring coordinates, the different process control monitoring coordinates arranged substantially equally distributed on the wafer; and
determining or approximating, using the at least one machine learning algorithm, wafer level test values for all individual chips on the wafer.

6. The computer-implemented method according to claim 1, further comprising:
generating a message when at least one of the at least three approximated wafer level test values is outside of a predetermined range or exceeds or falls below a predetermined threshold value,
wherein the generated message is based on the quality state of respective chips.

7. The computer-implemented method according to claim 1, further comprising:
checking the machine learning algorithm by comparing predicted wafer level test values with actual measured wafer level test values on the wafer by determining deviations;
determining a maximum error value of the deviations; and
stopping applying the machine learning algorithm when the maximum error value exceeds a set threshold value.

8. The computer-implemented method according to claim 1, wherein a computer program includes program code to execute at least portions of the method on a computer.

9. A non-transitory computer-readable data carrier comprising program code of a computer program to execute at least portions of the method according to claim 1 when the computer program is executed on a computer.

10. A computer-implemented method for providing a training machine learning algorithm for approximating wafer level test values based on process control monitoring metrics at different process control monitoring coordinates of a wafer, the method comprising:
receiving a first training data set comprising a plurality of process control monitoring metrics at different process control monitoring coordinates of the wafer;
receiving a second training data set comprising a plurality of approximated wafer level test values; and
training the machine learning algorithm by an optimization algorithm that calculates an extreme value of a loss function for approximating wafer level test values based on process control monitoring metrics at different process control monitoring coordinates of the wafer.

11. A system for determining a quality state of a wafer, comprising:
a first computing unit configured to provide at least three process control monitoring metrics of the wafer, each of the process control monitoring metrics collected on the wafer at a different process control monitoring coordinate;
an input device configured to input the at least three process control monitoring metrics and the process control monitoring coordinates into at least one machine learning algorithm, the at least one machine learning algorithm configured to output at least three approximated wafer level test values; and
a determination device configured to determine the quality state of the wafer based on the outputted at least three approximated wafer level test values.

12. The system according to claim 11, further comprising:
a system for providing a training machine learning algorithm for approximating the wafer level test values based on the process control monitoring metrics, the system including:
a receiving device configured to receive (i) a first training data set comprising a plurality of the process control monitoring metrics at different process control monitoring coordinates of the wafer, and (ii) a second training data set comprising a plurality of the approximated wafer level test values; and
a training calculation unit configured to train the at least one machine learning algorithm by an optimization algorithm that calculates an extreme value of a loss function for approximating the wafer level test values based on the process control monitoring metrics at the different process control monitoring coordinates of the wafer.
